(19) United States
(12) Patent Application Publication
(10) Pub. No.: US 2004/0198066 A1
(43) Pub. Date: Oct. 7, 2004

(54) Using supercritical fluids and/or dense fluids in semiconductor applications

(75) Inventor: Steven Verhaverbeke, San Francisco, CA (US)

Correspondence Address: Patent Counsel, APPLIED MATERIALS, INC., P.O. Box 450A, Santa Clara, CA, 95052, US

(73) Assignee: Applied Materials, Inc.

(21) Appl. No.: 10/394,465

(22) Filed: Mar. 21, 2003

(51) Int. Cl. H01L 21/302

(52) U.S. Cl. 438/745

(57) ABSTRACT

Embodiments of the present invention generally relate to methods and apparatuses using supercritical fluids and/or dense fluids in semiconductor applications. In one embodiment, a substrate structure is dried by applying a supercritical fluid, a dense fluid, or combinations thereof. In another embodiment, a substrate structure is cleaned by applying a supercritical fluid, a dense fluid, or combinations thereof. In still another embodiment, a low-k material layer is repaired by applying a supercritical fluid, a dense fluid, or combinations thereof. In yet another embodiment, a photoresist layer is stripped by applying a supercritical fluid, a dense fluid, or combinations thereof. In another embodiment, a porous low-k material layer is deposited by applying a supercritical fluid, a dense fluid, or combinations thereof.

### BACKGROUND OF THE INVENTION

1. Field of the Invention

Embodiments of the present invention generally relate to methods and apparatuses using supercritical fluids and/or dense fluids in semiconductor applications. More particularly, embodiments of the present invention relate to methods and apparatuses using supercritical fluids and/or dense carbon dioxide in processing of porous low-k materials.

2. Description of the Related Art

Organic solvents have been used in various cleaning applications. For example, hydrocarbon solvents have been used in dry cleaning of garments and fabrics. Similarly, chlorofluorocarbons (CFC's) have been used to clean electronic parts. Problems with the use of organic solvents include the environmental risks and disposal costs of these substances.

Carbon dioxide in its supercritical fluid state has been investigated as a replacement for organic solvents in cleaning applications. Advantages of supercritical carbon dioxide over organic solvents include the unique properties of supercritical fluids and the reduced environmental risks in the use of carbon dioxide. For substances which exhibit supercritical fluid properties, when the substance is above its critical point (critical temperature and critical pressure), the phase boundary between the gas phase and liquid phase disappears, and the substance exists in a single supercritical fluid phase. In the supercritical fluid phase, a substance assumes some of the properties of a gas and some of the properties of a liquid. For example, supercritical fluids have diffusivity properties similar to gases but solvating properties similar to liquids. Therefore, supercritical fluids have good cleaning properties.

One problem with prior attempts of using supercritical carbon dioxide in semiconductor cleaning applications is that the advantages of using supercritical fluid technology have not outweighed using other cleaning technologies. Therefore, there is a need for improved apparatuses and methods of utilizing supercritical fluids in semiconductor processing.

### SUMMARY OF THE INVENTION

Embodiments of the present invention generally relate to methods and apparatuses using supercritical fluids and/or dense fluids in semiconductor applications. In one embodiment, a substrate structure is dried by applying a supercritical fluid, a dense fluid, or combinations thereof. In another embodiment, a substrate structure is cleaned by applying a supercritical fluid, a dense fluid, or combinations thereof. In still another embodiment, a low-k material layer is repaired by applying a supercritical fluid, a dense fluid, or combinations thereof. In yet another embodiment, a photoresist layer is stripped by applying a supercritical fluid, a dense fluid, or combinations thereof. In another embodiment, a porous low-k material layer is deposited by applying a supercritical fluid, a dense fluid, or combinations thereof.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of one embodiment of a processing chamber adapted to apply a supercritical fluid and/or a dense fluid to a substrate in which the fluid is heated inside the chamber.

FIG. 2 is a schematic cross-sectional view of one embodiment of a processing chamber adapted to apply a supercritical fluid and/or a dense fluid to a substrate in which the fluid is heated in-line.

FIGS. 3A-3F are schematic cross-sectional views of one example of a substrate structure at various stages of semiconductor processing.

FIG. 4 is a flow chart of one embodiment of an application of drying a porous low-k material layer with a supercritical fluid and/or dense fluid.

FIG. 5 is a flow chart of one embodiment of an application of cleaning a substrate structure with a supercritical fluid and/or dense fluid after drying stripping.

FIG. 6 is a flow chart of one embodiment of an application of using a supercritical fluid and/or a dense fluid to repair a low-k material after drying stripping.

FIG. 7 is a flow chart of one embodiment of using a supercritical fluid and/or a dense fluid to strip a photoresist layer.

FIG. 8 is a flow chart of one embodiment of using a supercritical fluid and/or a dense fluid to clean the pores of a porous low-k material.

FIG. 9 is a schematic top view of one embodiment of an integrated system.

### DETAILED DESCRIPTION OF THE PREFERRED EMBODIMENT

Embodiments of the present invention generally relate to methods and apparatuses using supercritical fluids and/or dense fluids in semiconductor applications. Examples of substances which may be used to advantage as supercritical fluids and/or dense fluids include, but are not limited to, carbon dioxide, xenon, argon, helium, krypton, nitrogen, methane, ethane, propane, pentane, ethylene, methanol, ethanol, isopropanol, isobutanol, cyclohexanol, ammonia, nitrous oxide, oxygen, silicon hexafluoride, methyl fluoride, chlorotrifluoromethane, water, and combinations thereof.

The term “supercritical fluid” as used herein refers to a substance above its critical point. The term “dense fluid” as used herein refers to a substance at or below its critical point. Dense fluid preferably comprises a substance at or near its critical point. In certain embodiments, a dense fluid comprises a substance that is at a state in which its density is at least ⅕, preferably at least 1/3, more preferably at least ½, the density of the substance at its critical point.

In one embodiment, a substrate may be processed by applying a supercritical fluid thereto. In another embodiment, a substrate may be processed by applying a dense fluid thereto without the substance reaching a supercritical state. In still another embodiment, a substrate may be processed by applying a substance thereto in which the substance is phase modulated between a supercritical fluid state and a dense fluid state. A dense fluid may have a high solvating and diffusivities properties similar to a supercritical fluid. In one aspect, an apparatus adapted to apply a supercritical fluid to a substrate provides a supercritical fluid with greater solvating strength and diffusivity over a dense fluid. In another aspect, an apparatus adapted to only apply a dense fluid to a substrate is less complex than an apparatus adapted to apply a supercritical fluid due to the relatively higher temperatures and pressures used to achieve a supercritical fluid state.

In one preferred embodiment, the supercritical fluid and/or dense fluid used is carbon dioxide or xenon, more preferably carbon dioxide is used. In one aspect, carbon dioxide may be used to advantage as a supercritical fluid and/or dense fluid due to carbon dioxide's relatively low critical pressure (Pc=1050 psi) and relatively low critical temperature (Tc=31° C.) in comparison to other substances. In addition, carbon dioxide possesses less environmental risks in comparison to other substances which exhibit supercritical fluid properties. In one embodiment, dense carbon dioxide fluid comprises carbon dioxide at a temperature at least about 18° C. and at a pressure at least about 500 psi, and preferably comprises carbon dioxide at a temperature at least about 25° C. and at a pressure at least about 800 psi.

In another embodiment, the supercritical fluid and/or dense fluid used is a fluid with a critical pressure below 4,500 psi, preferably below 2,000 psi, and/or a fluid with a critical temperature below 200° C., preferably below 120° C.

Supercritical fluids and/or dense fluids, such as carbon dioxide, may be used to advantage in processing a variety of materials used in semiconductor applications. For example, supercritical fluids and/or dense fluids are useful in processing of porous low-k materials. Examples of porous low-k materials include organosilanes or organosiloxanes, such as Black Diamond™, available from Applied Materials, Inc. of Santa Clara, Calif.; organo-silicate-glass (OSG); tetraethylorthosilicate (TEOS); methylsilsesquioxane (MSQ); hydrido silsesquioxane (HSQ); MSQ-HSQ copolymers; silsesquioxane HOSP; other Si-containing material; other porous polymers; and any other suitable material. Preferably, the porous low-k materials comprise an organosilanes or organosiloxanes. One example of an organosilanes or organosiloxanes is described in U.S. Pat. No. 6,348,725, issued Feb. 19, 2002, which is incorporated by reference herein to the extent not inconsistent with the present disclosure.

Depending on the application, other optional components, such as co-solvents, surfactants, chelating agents, reactants, and combinations thereof, may be used in conjunction with the supercritical fluid and/or dense fluid. Examples of co-solvents include, but are not limited to, alcohols, halogenated solvents, esters, ethers, ketones, amines, amides, aromatics, aliphatic hydrocarbons, olefins, synthetic and natural hydrocarbons, organosilicones, alkyl pyrrolidones, paraffins, petroleum-based solvents, other suitable solvents, and mixtures thereof. The co-solvents may be miscible or immiscible with the supercritical fluid and/or dense fluid. Examples of chelating agents include, but are not limited to, chelating agent containing one or more amine or amide groups, such as ethylenediaminetetraacetic acid (EDTA), ethylenediaminedihyroxyphenylacetic acid (EDDHA), ethylenediamine, or methyl-formamide or other organic acids, such as iminodiacetic acid or oxalic acid. The term “surfactants” as used herein includes compounds have one or more polar groups and one or more non-polar groups. It is believed that the surfactants help alter the interfacial characteristics of the supercritical fluid and/or dense fluid. Examples of reactants include, but are not limited to silicon-containing compounds, oxidizing agents, carbon-containing compounds, other reactants, and combinations thereof.

Chambers

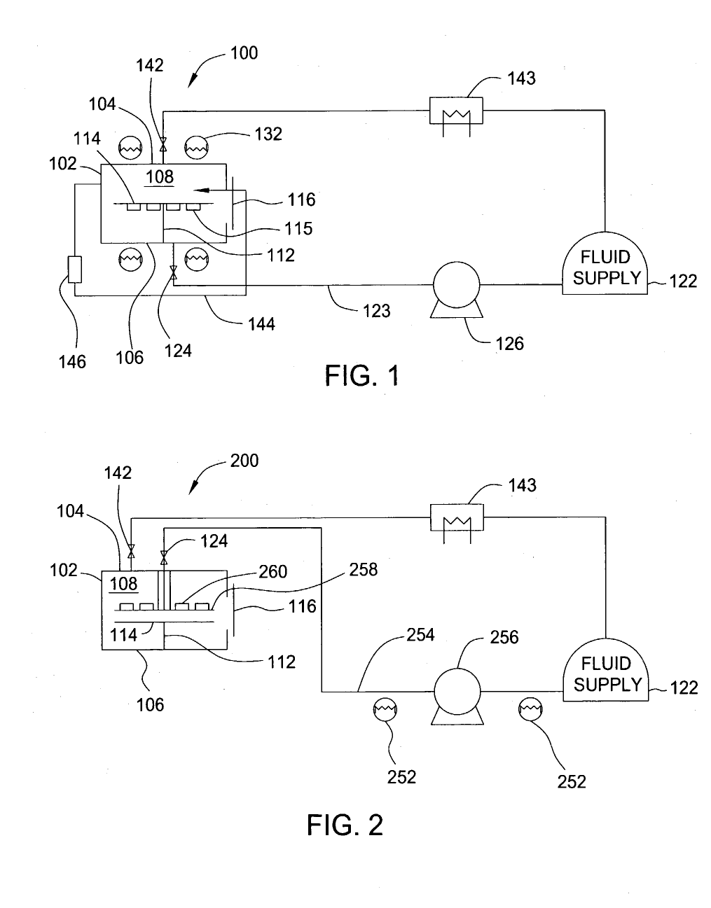

FIG. 1 is a schematic cross-sectional view of one embodiment of a processing chamber 100, adapted to apply a supercritical fluid and/or a dense fluid to a substrate, in which the fluid is heated inside the chamber. The chamber 100 includes sidewalls 102, a top wall 104, and a bottom wall 106 which define an enclosure 108. In one embodiment, the volume of the enclosure 108 comprises a small volume to reduce the amount of fluid necessary to fill the enclosure 108. In one embodiment, the chamber 100 is adapted to process 300 mm diameter substrates and has a volume of about 10 liters or less, more preferably about 5 liters or less. The chamber 100 may include a slit valve 116 to provide access for a robot to transfer and receive substrates from the enclosure 108. A substrate support 112 comprising a platter 114 is adapted to support a substrate within the enclosure 108. In one embodiment, the platter 114 defines a substrate receiving surface for receiving a substrate. The platter 114 may be adapted to rotate the substrate during processing.

The chamber 100 may optionally further include one or more acoustic or sonic transducers 115. As shown, the transducers 115 are located on the substrate support 112 but may be located in other areas of the enclosure 108. The transducers 115 create acoustic or sonic waves directed towards the surface of a substrate to help agitate the fluid. In other embodiments, the transducers may comprise a rod, plunger, or plate located within the enclosure. Other aspects and embodiments of a substrate support adapted to provide sonic agitation are disclosed in U.S. patent application Ser. No. 09/891,849, filed Jun. 25, 2001 and in U.S. patent application Ser. No. 09/891,791, filed Jun. 25, 2001, both of which are herein incorporated by reference in their entirety to the extent not inconsistent with the present disclosure.

A fluid line 123 couples a fluid supply 122, such as a carbon dioxide fluid supply, and a fluid inlet 124 to the chamber 100. A pump 126 may be disposed on the fluid line 123 between the fluid inlet 124 and the fluid supply 122 for delivering the fluid from the fluid supply 122 into the enclosure 108 of the chamber 100.

One or more heating elements 132 are disposed proximate or inside the walls 102, 104, 106 of the chamber 100. The heating elements 132 may comprise resistive heating elements, fluid channels for a heat control fluid, and/or other heating devices. The heating elements 132 heat the fluid inside the enclosure 108 to a desired temperature of the heated fluid. The chamber 100 may also optionally include cooling elements.

The chamber 100 may further include an optional loop 144 for re-circulating the fluid to and from the chamber 100. The loop 144 may further include a filter 146, such as an activated charcoal filter, to help purify the fluid. In one aspect, the loop 144 helps produce a laminar flow of the fluid within the enclosure 108 and helps prevent a stagnant fluid bath. It is believed that a laminar flow helps to sweep particles away from the substrate and to prevent particles from re-depositing on the substrate.

A fluid outlet 142 is coupled to the chamber 100 for removal of the fluid from the enclosure 108. The fluid outlet 142 may release the fluid to atmosphere, may direct the used fluid to storage, or may recycle the fluid for re-use. As shown, the fluid outlet 142 is coupled to the fluid supply 122 to recycle the fluid for re-use. A condenser 143 may be coupled between the fluid outlet 142 and the fluid supply 122 to condense the fluid prior to being directed to the fluid supply 122.

As shown, the fluid inlet 124 is disposed at a bottom wall 106 of the chamber 100 while the fluid outlet 142 is disposed at the top wall 104 of the chamber 100. Of course, the fluid inlet 124 and the fluid outlet 142 may be disposed at other areas of the walls 102, 104, 106 of the chamber 100. In addition, the fluid inlet 124 may be optionally coupled to nozzles, showerhead, or other fluid delivery device to direct the fluid towards the substrate.

One example of a method of processing a substrate with a carbon dioxide fluid in chamber 100 comprises transferring a substrate through the slit valve 116 to the substrate support 112 and closing the slit valve 116. Carbon dioxide is pumped by pump 126 into the chamber 100 from the fluid supply 122 to a desired pressure of the carbon dioxide within the enclosure 108. The fluid inlet 124 is closed and the heating elements 132 heat the carbon dioxide to a desired temperature so that the carbon dioxide is at a supercritical fluid state and/or a dense fluid state. The carbon dioxide is optionally agitated through application of the transducers 115 and/or rotation of the substrate. The carbon dioxide fluid is optionally re-circulated within the enclosure 108 through loop 144. After the substrate has been processed with the carbon dioxide fluid for a desired time period, the fluid outlet 142 is opened and the carbon dioxide is vented or released to atmosphere, directed to the condenser 143, or directed to storage. In one embodiment, releasing the pressure of the chamber causes the carbon dioxide at a supercritical fluid state and/or a dense fluid state to be at a gas state which can be easily removed from the chamber 100. The substrate may be optionally heated during venting to prevent cooling of the substrate and to prevent moisture uptake. Other methods of processing a substrate with a supercritical fluid and/or dense fluid are also possible in chamber 100.

FIG. 2 is a schematic cross-sectional view of one embodiment of a processing chamber 200 adapted to apply a supercritical fluid and/or a dense fluid to a substrate in which the fluid is heated in-line. Some of the parts of chamber 200 of FIG. 2 are similar to the parts of chamber 100 of FIG. 1. As a consequence like part numerals have been used for clarity of description where appropriate.

The chamber 200 has one or more heating elements 252 heating a line 254 coupling the fluid supply 122 and the chamber 200. A pump/compressor 256 may be disposed on the line 254 to deliver the fluid to the enclosure 108. The heating elements 252 may be disposed before and/or after the pump/compressor 256. The line 254 is coupled to a fluid delivery device 258, such as a showerhead, nozzle, or plate, disposed above the substrate support 112. In one embodiment, the fluid is delivered as a supercritical fluid and/or a dense fluid by the fluid delivery device 258 (i.e. as opposed to delivering the fluid to the chamber and setting conditions inside the chamber to bring the fluid to a supercritical or dense fluid state). In one embodiment, the fluid exists as a supercritical fluid and/or dense fluid at a partial volume of the enclosure 108 proximate the substrate surface. In another embodiment, a supercritical fluid and/or dense fluid is supplied by the fluid delivery device 258 until the enclosure 108 is at a supercritical fluid and/or dense fluid state.

The fluid delivery device 258 may include optional transducers 260 adapted to create acoustic or sonic waves directed towards the surface of a substrate to help agitate the fluid. In other embodiments, the transducers may be disposed at other locations within the enclosure 108. In addition, the substrate support 112 may be adapted to rotate the substrate and/or the fluid delivery device may be adapted to rotate to help agitate the fluid. The chamber 200 may also optionally include heating and/or cooling elements proximate or inside the chamber walls.

One example of a method of processing a substrate with a carbon dioxide fluid in chamber 200 comprises transferring a substrate to the substrate support 112. Carbon dioxide is transferred by pump/compressor 256 from the fluid supply 122 through the fluid line 254 at a desired pressure. The heating elements 252 heat the carbon dioxide to a desired temperature as the fluid is being transferred though the fluid line 254. The fluid delivery device 258 delivers a supercritical carbon dioxide fluid and/or a dense carbon dioxide fluid to the substrate. The carbon dioxide is optionally agitated through application of the transducers 260, rotation of the substrate, and/or rotation of the fluid delivery device. The enclosure 108 may be pressurized or unpressurized during application of the supercritical carbon dioxide fluid and/or dense carbon dioxide fluid by the fluid delivery device 258. After application of the carbon dioxide to the substrate, the carbon dioxide is vented or released to atmosphere, directed to the condenser 143, or directed to storage. The substrate may be optionally heated during venting to prevent cooling of the substrate and to prevent moisture uptake. Other methods of processing a substrate with a supercritical fluid and/or dense fluid are also possible in chamber 200.

Applications

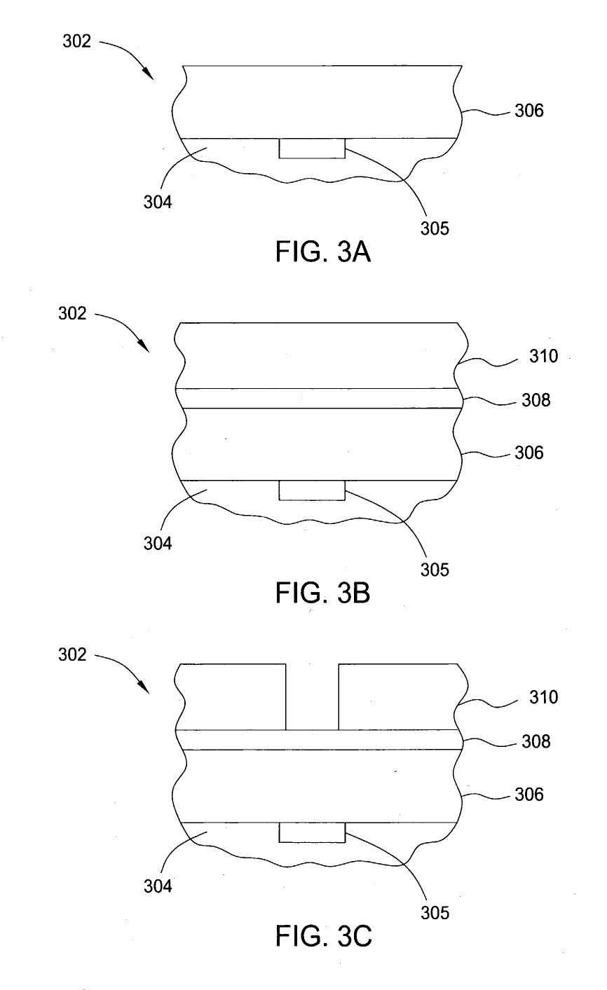

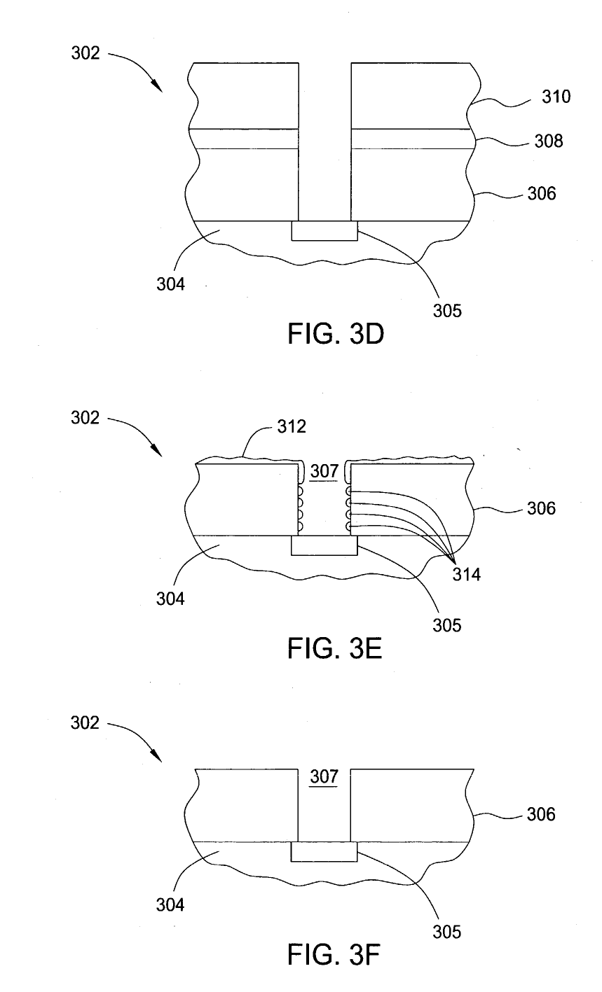

FIGS. 3A-3F are schematic cross-sectional views of one example of a substrate structure 302 at various stages of semiconductor processing. Supercritical fluids and/or dense fluids, such as a carbon dioxide fluid, are useful in processing of the substrate structure 302 at one or more stages of FIGS. 3A-3F, as described further below.

The substrate structure 302 comprises a substrate 304. The substrate 304 may be any substrate such as semiconductor wafers and glass substrates and may include materials formed thereover, such as dielectric materials, conductive materials, silicon layers, metal layers, etc. For example, as shown in the figures, the substrate 304 comprises a conductive feature 305.

In FIG. 3A, a porous low-k material layer 306, such as the porous low-k materials described herein, is formed over the substrate 304. In FIG. 3B, an anti-reflective coating 308 is formed over the porous low-k material layer and a photoresist layer 310 is formed over the anti-reflective coating 308. The photoresist layer 310 is exposed to a light to form an image thereon, such as either through a mask or a maskless process. In FIG. 3C, the photoresist layer 310 is developed by removal of unpolymerized resist. In FIG. 3D, the porous low-k material layer 306 is etched, such as through a dry etch, to form apertures 307 therein, such as for the formation of vias, contacts, trenches, interconnects. In FIG. 3E, the photoresist layer 308 and the anti-reflective coating 310 is stripped. One prior art method of stripping is through a dry strip. Typically, after a dry strip, photoresist residue 312 may be present on the top surface of the porous low-k material layer 306 and/or on the walls of the apertures 307. In addition, conductive material residues 314 may be present on the walls of the aperture 307 due to sputtering of the conductive material feature 305. In FIG. 3F, the substrate structure 302 is cleaned to remove residues 312, 314 from the substrate structure 302.

For clarity of description, applications of processing a substrate structure with a supercritical fluid and/or a dense fluid, such as carbon dioxide fluid, will be described in references to the substrate structure 302 of FIGS. 3A-3F. The present method includes processing of other types of substrate structures or processing at other stages of semiconductor processing. Processing of a substrate structure with a supercritical fluid and/or a dense fluid may performed in the chamber 100 of FIG. 1, chamber 200 of FIG. 2, or other single-substrate or batch apparatuses.

I. Drying/Removing Water

One embodiment of the present method comprises drying a substrate structure by applying a supercritical fluid and/or a dense fluid thereto. In one embodiment, a carbon dioxide fluid is used at a pressure between about 1,000 psi and about 5,000 psi and a temperature at least about 31° C. In another embodiment, the carbon dioxide fluid further includes a co-solvent, such as methanol. Drying of the substrate structure with a supercritical fluid and/or dense fluid may be accomplished without the need for prior art vacuum bakes.

In one embodiment, a porous material layer, such as the porous low-k material layer 306 of the substrate structure 302 shown in FIG. 3F, may be dried to advantage by applying a supercritical fluid and/or a dense fluid thereto. The porous low-k material layer 306 acts like a sponge and takes up liquids very easily. As a consequence, the pores of the porous material layer 306 are difficult to dry out. The sponge-like nature of porous low-k materials is exacerbated after dry etch and dry ash because the porous low-k material is initially hydrophobic as deposited, but behaves hydrophilic after dry etch and dry stripping due to the formation of silanol bonds. Therefore, after a wet clean of a substrate structure after dry stripping, drying of the substrate structure is necessary. One problem with prior art methods of drying the substrate structure comprising a porous material layer with vacuum bake is a long process time, such as a vacuum bake of about 420° C. under a pressure of 1 Torr for about 2 hours. Drying of the porous low-k material with a supercritical fluid and/or dense fluid may be accomplished without the need for prior art vacuum bakes.

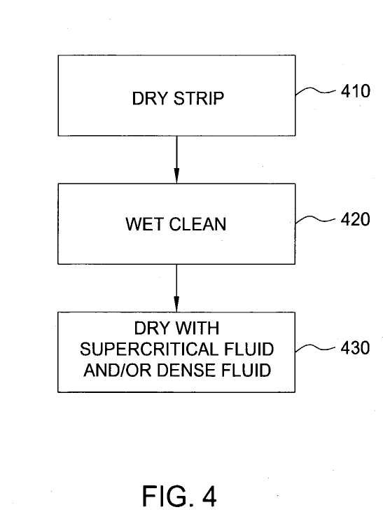

FIG. 4 is a flow chart of one embodiment of an application of drying a porous low-k material layer with a supercritical fluid and/or dense fluid. In step 410, a substrate structure including a patterned photoresist is dry stripped of the resist. In step 420, the substrate structure is cleaned with a wet clean. In step 430, the substrate structure, such as substrate structure 302 of FIG. 3F, is dried with a supercritical fluid and/or dense fluid.

Other substrate structures may be dried with a supercritical fluid and/or a dense fluid. In one embodiment, high aspect ratio apertures, such as for example the aperture 307 of the substrate structure 302 shown in FIG. 3F, may be dried to advantage with a supercritical fluid and/or a dense fluid. High aspect ratio apertures also act like a sponge taking up liquids very easily and are difficult to dry out. In still another embodiment, photoresist patterns after development, such as the photoresist layer 310 of FIG. 3C, may be dried to advantage with a supercritical fluid and/or a dense fluid. After development with an aqueous solution, water may remain in between the photoresist patterns, which again act like a sponge. When the water trapped in between the photoresist patterns starts to evaporate, the resist patterns collapse due to the surface tension attraction. A supercritical fluid and/or a dense fluid can be used to advantage to dry the above substrate structure and other substrate structures.

II. Cleaning of the Surface of the Substrate Structure

One embodiment of the present method comprises cleaning a substrate structure by applying a supercritical fluid and/or a dense fluid thereto. In one embodiment, a carbon dioxide fluid is used at a pressure between about 1,000 psi and about 5,000 psi and a temperature at least about 31° C. In another embodiment, the carbon dioxide fluid further includes a co-solvent, such as methanol, surfactants, chelating agents, and combinations thereof. Cleaning of the substrate structure with a supercritical fluid and/or dense fluid may be accomplished without the need for a wet clean.

In one embodiment, supercritical fluid and/or dense fluid may be used to clean a substrate structure after dry stripping. For example, supercritical fluid and/or dense fluid may be used to remove or clean photoresist residue 312 from the porous low-k material layer 306 of substrate structure 302 shown in FIG. 3E. In one embodiment, the supercritical fluid and/or dense fluid further includes a chelating agent to help remove or clean conductive material residue 314. In one aspect, cleaning of residue from a substrate structure with a supercritical fluid and/or dense fluid may be accomplished without the need for a wet clean. As a consequence, using a supercritical fluid and/or dense fluid to clean a substrate structure avoids the associated problems of using a wet clean.

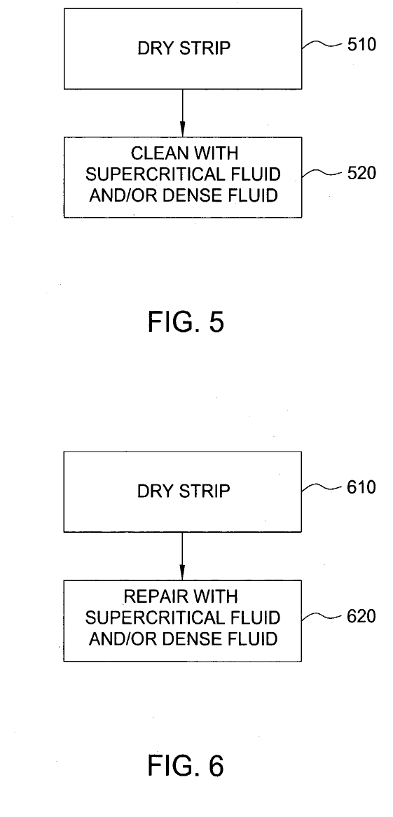

FIG. 5 is a flow chart of one embodiment of an application of cleaning a substrate structure with a supercritical fluid and/or dense fluid after dry stripping. In step 510, a substrate structure having a photoresist is dry stripped of the photoresist. In step 520, the surface of the substrate structure, such as substrate structure 302 of FIG. 3E, is cleaned with a supercritical fluid.

III. Repair of Low-K Material After Dry Stripping

One embodiment of the present method comprises repairing of low-k material, such as porous low-k material, by applying a supercritical fluid and/or a dense fluid thereto. In one embodiment, a carbon dioxide fluid is used at a pressure between about 1,000 psi and about 5,000 psi and a temperature at least about 31° C. In another embodiment, the carbon dioxide fluid further includes reactants, such as silicon tetrachloride and methanol.

Not wishing to be bound by theory unless set forth in the claims, in one aspect, repair of the low-k material lowers the k-value of the low-k material. Typically after dry stripping of the photoresist, the low-k material layer will be silanol terminated. Because the silanol bond is extremely polar, silanol termination increases the k-value of the dielectric material. In addition, the polar nature of the silanol bond cause the low-k material layer to behave hydrophilic. It has been shown that supercritical fluid can be used to replace silanol termination surface with a non-polar termination. For example, supercritical carbon dioxide with a silicon source, such as silicon tetrachloride, and with methanol can replace the silanol termination surface with a methyl termination surface.

FIG. 6 is a flow chart of one embodiment of an application of using a supercritical fluid and/or a dense fluid to repair a low-k material after drying stripping. In step 610, a substrate structure having a photoresist is dry stripped of the resist. In step 620, the low-k material layer, such as substrate structure 302 of FIG. 3E or FIG. 3F, is repaired with a supercritical fluid and/or dense along with one or more reactants.

IV. Photoresist Removal

One embodiment of the present invention comprises stripping of a photoresist by applying a supercritical fluid and/or dense fluid. In one embodiment, a carbon dioxide fluid is used at a pressure between about 1,000 psi and about 5,000 psi and a temperature at least about 31° C. In another embodiment, the carbon dioxide fluid further includes a co-solvent, a surfactant, or combinations thereof.

Not wishing to be bound by theory unless set forth in the claim, it is believed that a supercritical fluid and/or a dense fluid is advantageous in the removal of resist since dry stripping of the resist and the accompanying damages to the dielectric layer is avoided.

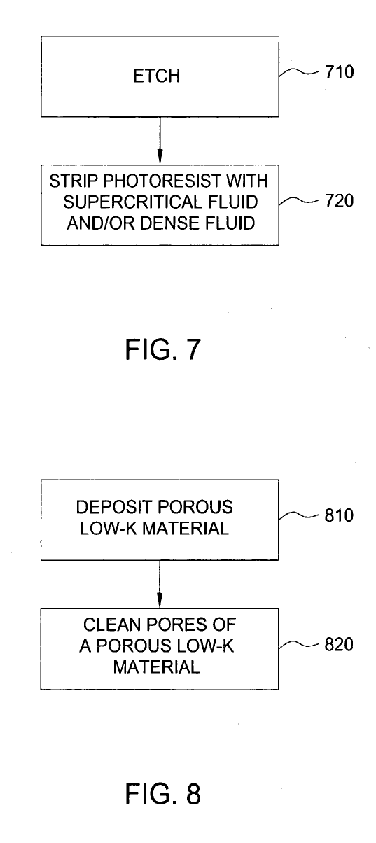

FIG. 7 is a flow chart of one embodiment of using a supercritical fluid and/or a dense fluid to strip a photoresist layer. In step 710, the substrate structure is etched to form apertures therein. In step 720, the photoresist layer of a substrate structure, such as substrate structure 302 of FIG. 3D, is stripped using a supercritical fluid and/or a dense fluid. If there is an anti-reflective coating, the anti-reflective coating may also be stripped using a supercritical fluid.

Other photoresists at other stages in semiconductor processing may be removed. In one embodiment, a supercritical fluid and/or dense fluid can used to develop a photoresist. The supercritical fluid and/or dense fluid can be used without a developer or with a developer, such as TMAH. In another embodiment, supercritical fluid and/or dense can be used to cure a photoresist layer. The supercritical fluid and/or dense fluid removes solvent from the photoresist at a low temperature. As a consequence, the photoresist retains the shape and integrity of the patterned features. One of the benefits is that a high temperature bake, which can alter the shape of the patterns, is avoided.

V. Cleaning Up Pores of a Porous Low-k Material

One embodiment of the present invention comprises cleaning of the inside of the pores of a porous low-k material by applying a supercritical fluid and/or dense fluid thereto. In one embodiment, a carbon dioxide fluid is used at a pressure between about 1,000 psi and about 5,000 psi and a temperature at least about 31° C.

After deposition of a porous low-k material, such as by spin-on or chemical vapor deposition, the inside of the pores may contain residues from either the carrier solvent or the precursors. These solvent and precursor residues inside the pores increase the k-value of the low-k material layer and can cause early failures in the field. It has been shown that supercritical carbon dioxide can penetrate the pores of a porous low-k material and transport solvent and precursor residues out of the pores.

FIG. 8 is a flow chart of one embodiment of using a supercritical fluid and/or a dense fluid to clean the pores of a porous low-k material. In step 810, a porous low-k material is deposited. In step 810, pores of porous low-k material layer of a substrate structure, such as substrate structure 302 of FIG. 3A, are cleaned with a supercritical fluid and/or dense fluid.

Other Applications

Processing with a supercritical fluid can be used for other applications. In another application, a supercritical fluid can be used to remove adsorbed contaminants, such as adhered ions and compounds. For example, electroplating can leave adhered F⁻, H⁺, and H₂O. Adhered compounds, such as NH₃, can cause problematic resist poising. Adhered ions, such as F⁻, H⁺, NH₄⁺ can cause problematic voiding in porous films.

In another application, a supercritical fluid can be used to deposit porous low-k dielectrics. Because the supercritical fluid has low surface tension, diffusivity of a gas, density of a liquid, a film that is mechanically stronger and has a lower-k value is formed even with the same precursors in comparison to deposition by spin-on or by chemical vapor deposition. It is believed that using a supercritical fluid as a solvent during deposition causes the film to have a lower amount of dangling bond and imperfect cells in comparison to deposition by spin-on or by chemical vapor deposition.

Other applications further include CMP cleaning, resist coating, FEOL cleaning, copper barrier deposition, copper seed deposition, electroless copper deposition, and electroless cobalt deposition.

Platforms

The applications of processing substrates as disclosed herein may be carried out in one or more single chamber systems, in one or more mainframe systems having a plurality of chambers, in separate processing systems, in an integrated processing system, or in combinations thereof.

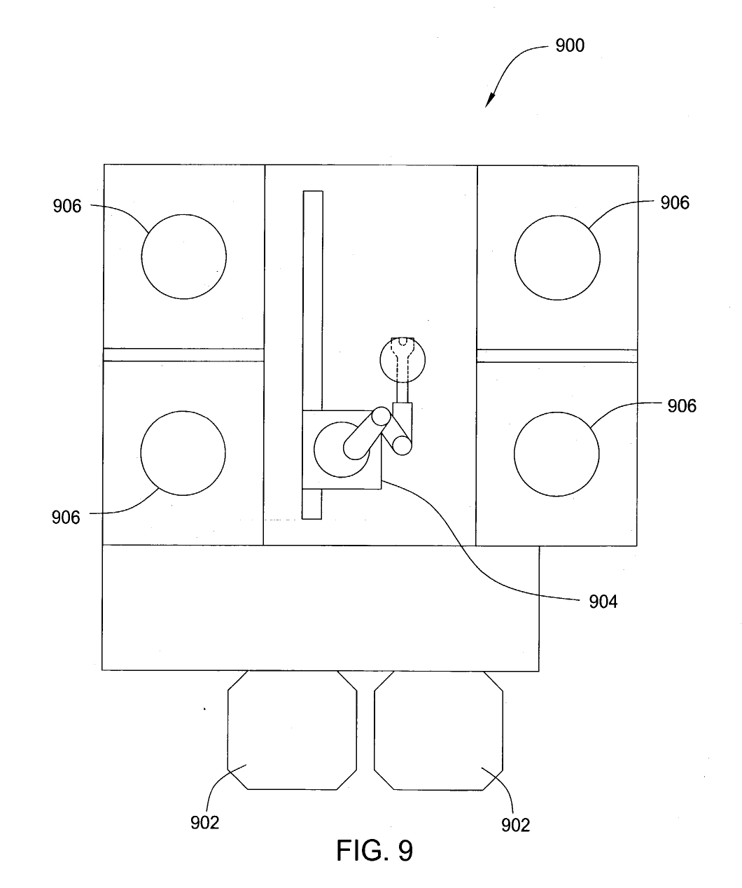

FIG. 9 is a schematic top view of one embodiment of an integrated system 900 capable of performing the processes disclosed herein. As shown in the figure, the integrated system 900 is a LINK™ platform, available from Applied Materials, Inc., located in Santa Clara, Calif. The system 910 generally includes one or more substrate cassettes 902, one or more transfer robots 904, and one or more processing chambers 906.

One example of the system 900 adapted to perform the method as described in FIG. 4 comprises at least one of the chamber 906 adapted to provide a wet clean, such as a TEMPEST™ chamber, available from Applied Materials, Inc, located in Santa Clara, Calif. The system 900 further comprises at least one of the chambers 906 adapted to provide a supercritical fluid and/or a dense fluid, such as chamber 100 of FIG. 1 or chamber 200 of FIG. 2. The system 900 further optionally further comprises at least one chamber 906 adapted to provide a dry strip, such as an AXIOM™ chamber, available from Applied Materials, Inc., located in Santa Clara, Calif.

One example of the system 900 adapted to perform the method as described in FIG. 5 or FIG. 6 comprises at least one chamber 906 adapted to provide a dry strip, such as an AXIOM™ chamber, available from Applied Materials, Inc., located in Santa Clara, Calif. The system 900 further comprises at least one of the chambers 906 adapted to provide a supercritical fluid and/or a dense fluid, such as chamber 100 of FIG. 1 or chamber 200 of FIG. 2.

One example of the system 900 adapted to perform the method as described in FIG. 7 comprises at least one chamber 906 adapted to provide a dry etch, such as an eMAX™ chamber or a DPS™ chamber, available from Applied Materials, Inc., located in Santa Clara, Calif. The system 900 further comprises at least one of the chambers 906 adapted to provide a supercritical fluid and/or a dense fluid, such as chamber 100 of FIG. 1 or chamber 200 of FIG. 2.

One example of the system 900 adapted to perform the method as described in FIG. 8 comprises at least one chamber 906 adapted to deposit a low-k material, such as a Black Diamond™ CVD chamber, available from Applied Materials, Inc., located in Santa Clara, Calif. The system 900 further comprises at least one of the chambers 906 adapted to provide a supercritical fluid and/or a dense fluid, such as chamber 100 of FIG. 1 or chamber 200 of FIG. 2.

The above particular embodiments of the system 900 to perform the process as disclosed herein is provided to illustrate the invention and should not be used to limit the scope of the invention unless otherwise set forth in the claims.

While the foregoing is directed to embodiments of the present invention, other and further embodiments of the invention may be devised without departing from the basic scope thereof, and the scope thereof is determined by the claims that follow.

1-27. (Cancelled)

28. An apparatus for processing substrate structures, comprising:
a chamber comprising walls defining an enclosure, the chamber adapted to be pressurized to a pressure of at least about 1000 psi;
a substrate support disposed within the enclosure; and
one or more vibrational transducers disposed within the enclosure.

29. The apparatus of claim 28, further comprising one or more heating elements disposed at the walls of the chamber and a loop to re-circulate fluid to and from the chamber during processing.

30. The apparatus of claim 28, wherein the vibrational transducers are disposed on the substrate support.

31. An apparatus for processing substrate structures, comprising:
a chamber comprising walls defining an enclosure;
a substrate support disposed within the enclosure, the substrate support having a substrate receiving surface;
a fluid delivery device adapted to deliver a supercritical fluid or dense fluid to the substrate receiving surface;
a fluid supply;
a fluid line coupled between the fluid delivery device and the fluid supply; and
one or more heating elements disposed at the fluid line.

32. The apparatus of claim 31, further comprising one or more transducers disposed on the fluid delivery device.

33. The apparatus of claim 31, wherein the fluid delivery device is adapted to rotate.

34-40. (Cancelled)

41. The apparatus of claim 28, wherein the substrate support further comprises a substrate receiving surface adapted to rotate a substrate structure disposed thereupon during processing.

42. The apparatus of claim 28, wherein the one or more vibrational transducers comprise acoustic wave transducers.

43. The apparatus of claim 42 wherein the one or more acoustic wave transducers generate megasonic or ultrasonic sound waves.

44. The apparatus of claim 28, wherein the one or more vibrational transducers is selected from the group consisting of:
rods,
plungers, and
plates.

45. The apparatus of claim 31, wherein the substrate receiving surface is adapted to rotate a substrate structure disposed thereupon during processing.

46. The apparatus of claim 31, further comprising a slit valve to provide access for transferring substrates into and receiving substrates from the enclosure.

47. The apparatus of claim 31, further comprising one or more transducers disposed within the enclosure.

48. The apparatus of claim 47, wherein the one or more transducers comprise vibrational transducers.

49. The apparatus of claim 47, wherein the one or more transducers are disposed on the substrate support.

50. A system, comprising:
one or more first chambers adapted to perform a supercritical fluid and/or a dense fluid process comprising;
walls defining an enclosure;
a substrate support disposed within the enclosure, the substrate support having a substrate receiving surface;
a fluid delivery device adapted to deliver a supercritical fluid or dense fluid to the substrate receiving surface;
a fluid supply;
a fluid line coupled between the fluid delivery device and the fluid supply; and
one or more heating elements disposed at the fluid line;
one or more second chambers selected from the group consisting of:
a wet clean chamber,
a dry stripping chamber,
a dry etch chamber,
a porous low-k deposition chamber, and
combinations thereof; and
one or more transfer robots adapted to transfer substrates between the one or more first chambers and the one or more second chambers.

51. The system of claim 51, wherein the one or more first chambers are capable of holding a pressure of at least about 1,000 psi.

52. The system of claim 51, wherein the one or more second chambers comprise at least one wet clean chamber.

53. The system of claim 52, wherein the one or more second chambers further comprise at least one dry stripping chamber.

54. The system of claim 51, wherein the one or more second chambers comprise at least one dry stripping chamber.

55. The system of claim 51, wherein the one or more second chambers comprise at least one dry etch chamber.

56. The system of claim 51, wherein the one or more second chambers comprise at least one porous low-k deposition chamber.

57. An apparatus for processing substrate structures, comprising:
a chamber comprising walls defining an enclosure;
a substrate support disposed within the enclosure; and
one or more vibrational transducers disposed within the enclosure.

58. The apparatus of claim 57, further comprising:
one or more heating elements disposed at the walls of the chamber; and
a loop to re-circulate fluid to and from the chamber during processing.

59. The apparatus of claim 57, wherein the vibrational transducers are disposed on the substrate support.
